(19) United States
(12) Patent Application Publication
(10) Pub. No.: US 2026/0239528 A1
(43) Pub. Date: Aug. 13, 2026

(54) HIGH-VOLTAGE PRINTED CIRCUIT BOARD WITH INTEGRATED PLASMA DISCHARGE ELECTRODES FOR SCALABLE PLASMA-BASED WATER TREATMENT SYSTEMS

(71) Applicant: Black Spark Inc, Terryville, CT (US)

(72) Inventors: Gunnar Rohrman Stratton, Terryville, CT (US); Mikhail Vasilev, South Bend, IN (US)

(73) Assignee: Black Spark Inc, Terryville, CT (US)

(21) Appl. No.: 19/396,996

(22) Filed: Nov. 21, 2025

Related U.S. Application Data
(60) Provisional application No. 63/755,612, filed on Feb. 7, 2025.

(51) Int. Cl. H05K 1/02; C02F 1/46; C02F 1/461; C02F 101/36

(52) U.S. Cl. CPC H05K 1/0256; C02F 1/4608; C02F 1/46109; C02F 2101/36; C02F 2201/4616; H05K 2201/0104; H05K 2201/10015; H05K 2201/10174; H05K 2201/10181; H05K 2201/10265; H05K 2201/10393

(57) ABSTRACT

Disclosed are embodiments of an apparatus comprising a high-voltage printed circuit board (PCB) with discharge electrodes configured to emit plasma to the surface of a treated liquid for the degradation of per- and polyfluoroalkyl substances (PFAS) and other contaminants. Embodiments include aspects of integration of the discharge electrodes into the PCB, which eliminates the need for external wiring for each electrode, reducing complexity and failure points. Embodiments include aspects of built-in capacitor-diode circuits, which ensures that each discharge electrode has an isolated power circuit, allowing for independent and controlled plasma discharges.

### CROSS-REFERENCES

This application claims the benefit of U.S. Provisional Patent Application No. 63/755,612, entitled, “High-Voltage Printed Circuit Board with Integrated Electrodes for Scalable Plasma-Based Water Treatment Systems,” filed on 02/07/2025, the content of which is hereby incorporated by reference herein in its entirety.

### BACKGROUND OF THE INVENTION

Plasma-based water treatment is a promising technology for degrading per- and polyfluoroalkyl substances (PFAS) and other contaminants. However, current plasma systems suffer from scalability, complexity, and reliability issues due to their electrical configurations.

There are challenges in existing plasma-based water treatment systems. There is a challenge of complex wiring and assembly. Traditional systems require individual high-voltage wiring for each discharge electrode, creating cabling challenges when scaling to hundreds or thousands of electrodes. Running hundreds or thousands of high voltage cables into an airtight reactor enclosure is impractical, expensive and increases failure points. There is a challenge of electrode isolation and power distribution issues. Each discharge electrode typically requires a separate capacitor-diode circuit, which must be manually connected. These connections increase manufacturing costs, assembly time, and maintenance complexity.

A solution to the challenges is high-voltage PCB with integrated plasma electrodes. The disclosed embodiments provides a printed circuit board (PCB) with integrated discharge electrodes, capacitor-diode networks, and protective coatings, enabling a simpler, more scalable, and more reliable plasma-based water treatment system.

### DESCRIPTION

The present technology is a high-voltage PCB designed for large-scale plasma generation, with the following key features: 1) integration of discharge electrodes into the PCB, which eliminates the need for external wiring for each electrode, reducing complexity and failure points; 2) built-in capacitor-diode networks, which ensures that each electrode has an isolated power circuit, allowing for independent and controlled plasma discharges; 3) through-hole spring-clamp electrode connections, so each electrode is connected via a through-hole spring-clamp component, yielding secure yet removable connections without soldering, which significantly simplifies maintenance; 3) single-point connections for ground and high voltage, so the PCB features just one connection point each for common ground and the high voltage power source, and just two cables must pass through the reactor enclosure to operate any number of individual discharge electrodes; 4) slotted PCB for improved electrode isolation and gas flow, where precision-cut slots increase isolation between electrodes, reducing high-voltage arcing risks while allowing gas movement for enhanced plasma stability; 5) corrosion protection using urethane coating, so instead of an enclosure, the PCB is urethane-coated for high-voltage insulation and protection from moisture and harsh chemicals that tend to be produced by plasma and present in PFAS-contaminated liquids; 6) oil-filled potting box for capacitors, diodes, and fuses, where the capacitor-diode network is fully enclosed in an oil-filled potting box, which provides dielectric insulation and prevents high-voltage arcing and premature component failure, additionally fuses are also enclosed in this oil-filled environment to prevent circuit-wide failure in the event of capacitor shorts.

Embodiments of this technology provides a high-voltage PCB with integrated discharge electrodes, offering a simpler, more scalable, and more reliable approach to plasma-based water treatment systems. By eliminating external wiring, improving insulation, and enabling large-scale deployment, this system overcomes the limitations of traditional plasma generators and significantly enhances manufacturability, operability and therefore applicability of plasma-based technologies for treatment of PFAS-contaminated liquids.

### BRIEF DESCRIPTION OF FIGURES

FIG. 1 is a figure of a top-view of an embodiment of a PCB.

FIG. 2A is a figure of a top-view of an embodiment showing the supporting electrical circuitry.

FIG. 2B is a figure of a top-view of an embodiment the supporting electrical circuitry and an embodiment of traces which are shaped in the form of curvature, serpentine patterns, or edge chamfering.

FIG. 3A is a cross-sectional view of an embodiment of a PCB along the anterior cut-away line 121.

FIG. 3B is a partial cross-sectional view of a potting box filled with a conformable dielectric substance.

FIG. 3C is a partial cross-sectional view of a potting box filled with epoxy.

FIG. 4A is a side view of an embodiment of a capacitor-diode circuit.

FIG. 4B is a side view of an embodiment of a capacitor-diode circuit.

FIG. 5A is a side view of an embodiment of a discharge circuit.

FIG. 5B is a side view of an embodiment of a discharge circuit.

FIG. 6 is a cross-sectional view of an embodiment of a non-conductive substrate, a trace, and a conformal insulating coating.

FIG. 7 is a cross-sectional view of an embodiment of a non-conductive substrate and a conformal insulating coating.

FIG. 8 is a figure of a cross-sectional view of a capacitor-diode circuit and a conformal insulating coating.

FIG. 9 is a partial cross-sectional view of an embodiment of a discharge electrode mounted with solderless mechanical connectors.

FIG. 10 is a partial cross-sectional view of an embodiment of a discharge electrode mounted with through-hole spring-clamp connector terminals.

FIG. 11 is a figure of a cross-sectional view of an embodiment of a PCB along the lateral cut-away line 122 and shows the high voltage connections and high voltage source cable.

FIG. 12 is a figure of an embodiment of a generalized circuit diagram for the plasma-generating system.

FIG. 13 is a figure of an embodiment of a generalized circuit diagram for the plasma-generating system.

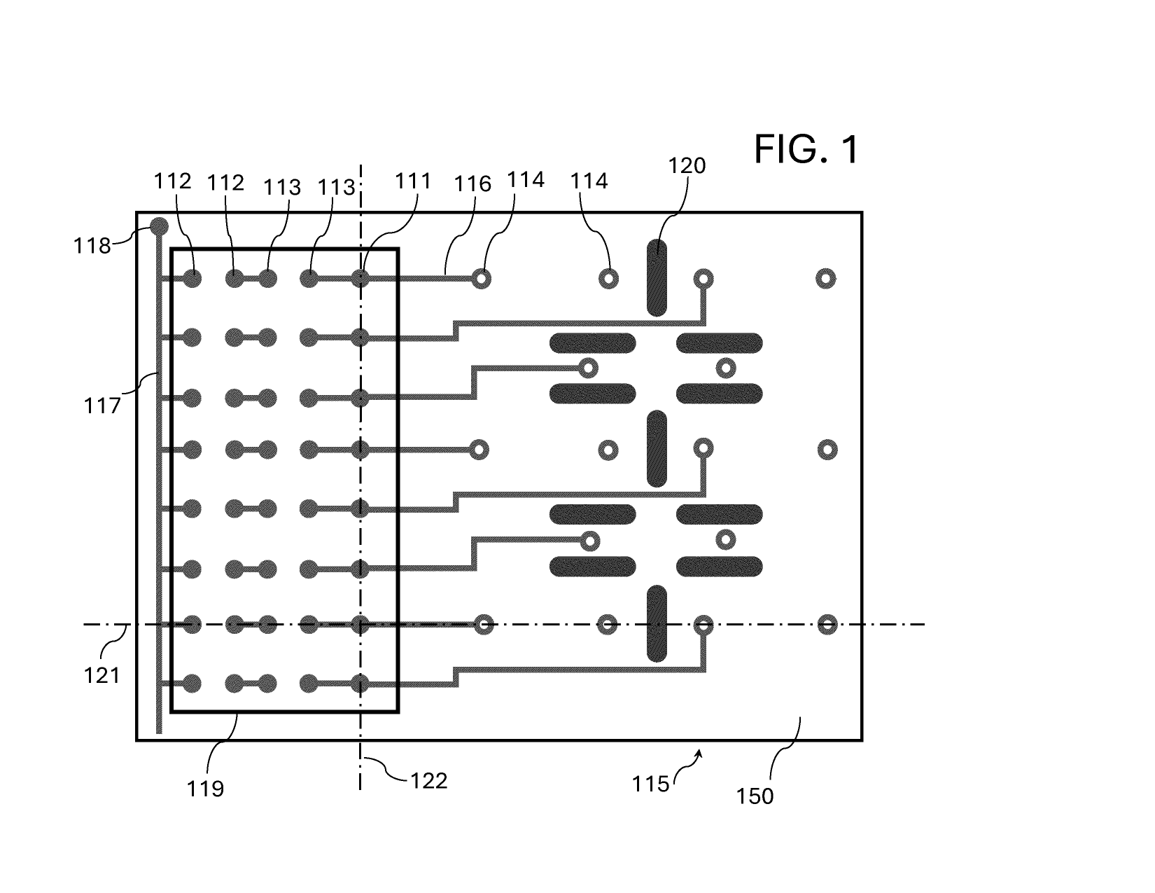

### DETAILED DESCRIPTION

An embodiment of the printed circuit board (PCB), also called PCB 115, has multiple characteristics.

The PCB 115 can withstand operating voltages in the range of 10-50 kV and therefore can be described as a high-voltage printed circuit board (PCB). The PCB 115 has a main board, called a non-conductive substrate 150. An embodiment of the non-conductive substrate 150 can be made of FR-4, chosen for its high dielectric strength (~20 kV/mm), low cost, high strength and durability, and wide availability, making it ideal for this application.

On the non-conductive substrate 150 are traces. A type of trace are high voltage traces 116. A type of trace are grounded traces 117. The high voltage trace 116 and grounded trace 117 are specially designed to prevent electrical arcing, using adequate spacing and a conformal insulting coating 140. A high voltage trace 116 and a grounded trace 117 are thick enough (0.5-5mm) to accommodate high transient currents during discharges. An embodiment of traces which are shaped in the form of curvature, serpentine patterns, or edge chamfering 550, which reduce electric field concentration and arcing risk.

An embodiment of a discharge electrode 215 is connected at each end to an electrode mounting pad 114. The discharge electrodes 215 as such are mechanically mounted to the PCB 115 and extend outward from the non-conductive substrate 150. The discharge electrode 215 is connected at each end to an electrode mounting pad 114 with an electrode connector 217. The electrode connector 217 can be a solderless type of connector, or also called solderless mechanical connector 229. A type of solderless mechanical connector 229 is a through-hole spring-clamp connector terminal 230. Other types of solderless connections can be used, such as sockets. The electrode connector 217 simplifies the removal and replacement of a discharge electrode 215. The solderless mechanical connector 229 simplifies the removal and replacement of a discharge electrode 215. The discharge electrodes 215 are removably mounted to facilitate easy replacement or customization.

In embodiments of the technology, the ends of the discharge electrode 215 go through the non-conductive substrate 150 through electrode through-holes 216, which are holes through the non-conductive substrate 150.

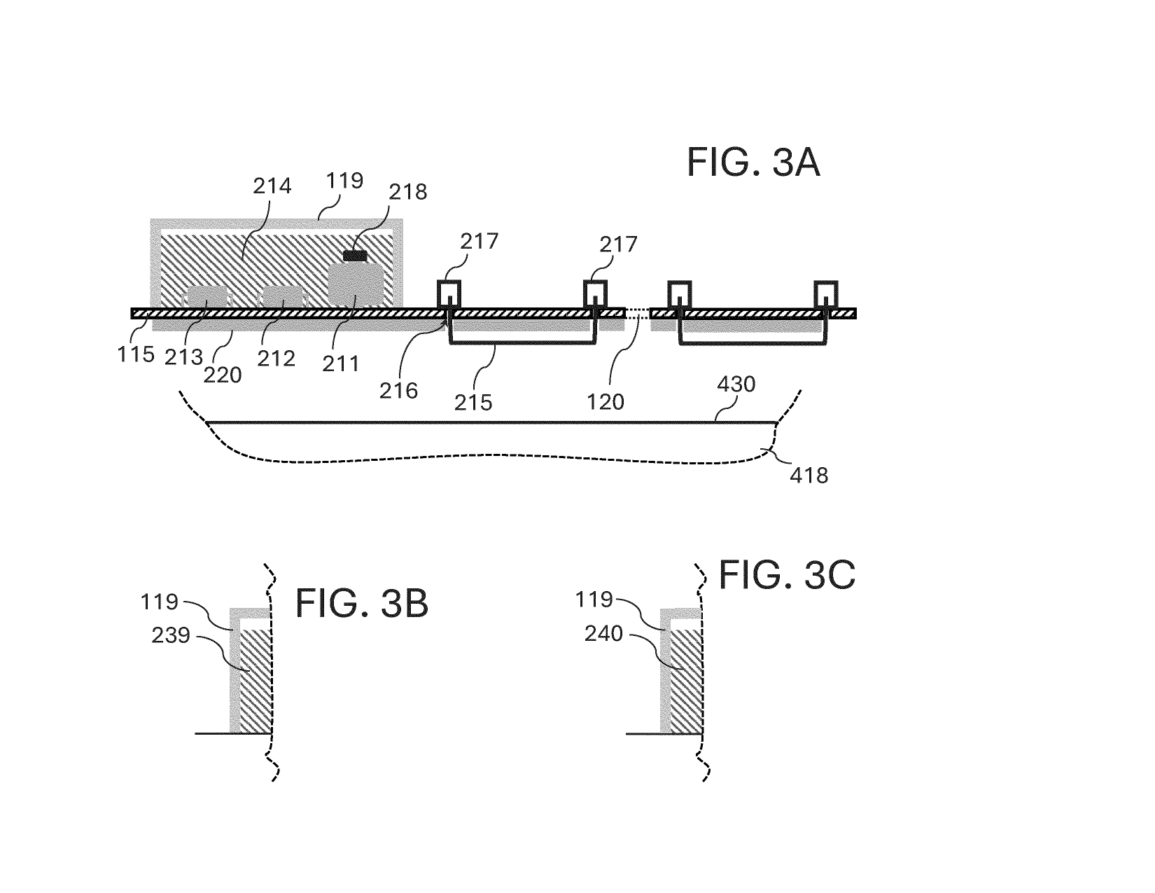

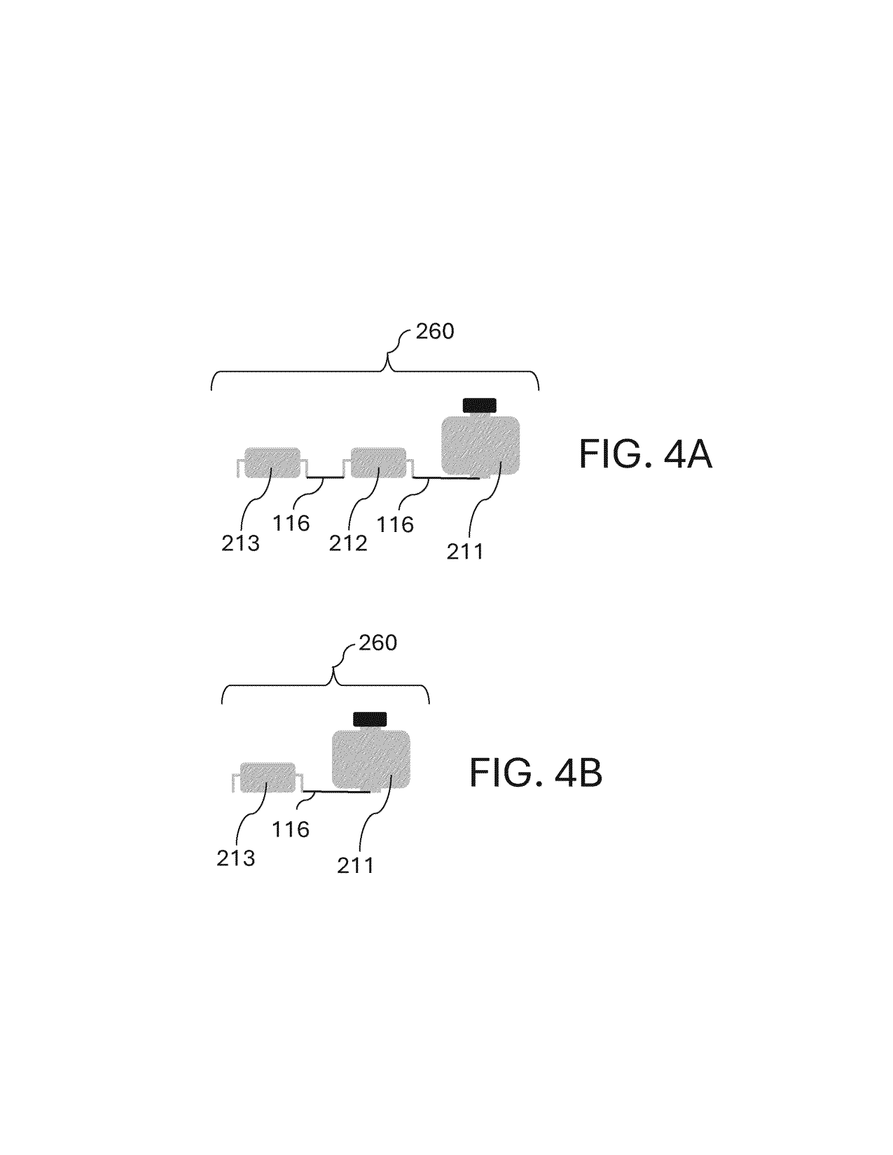

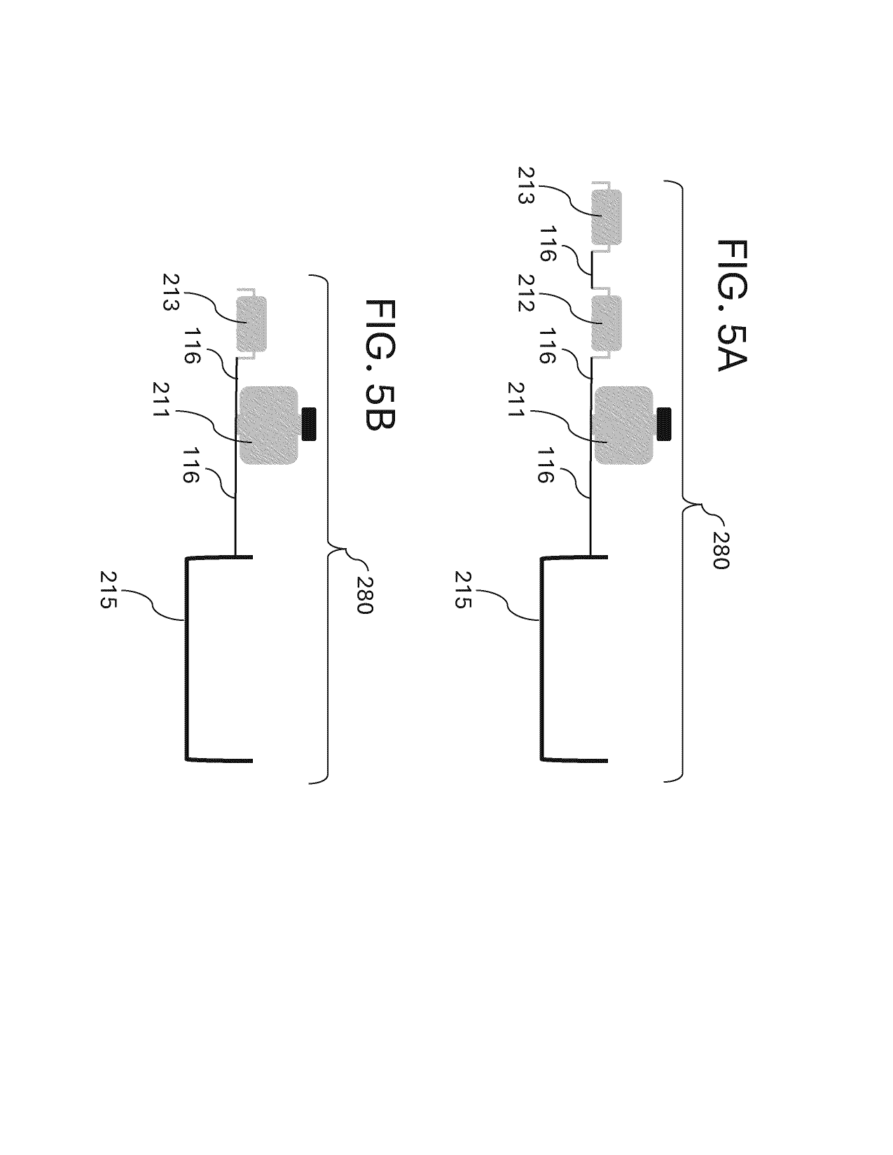

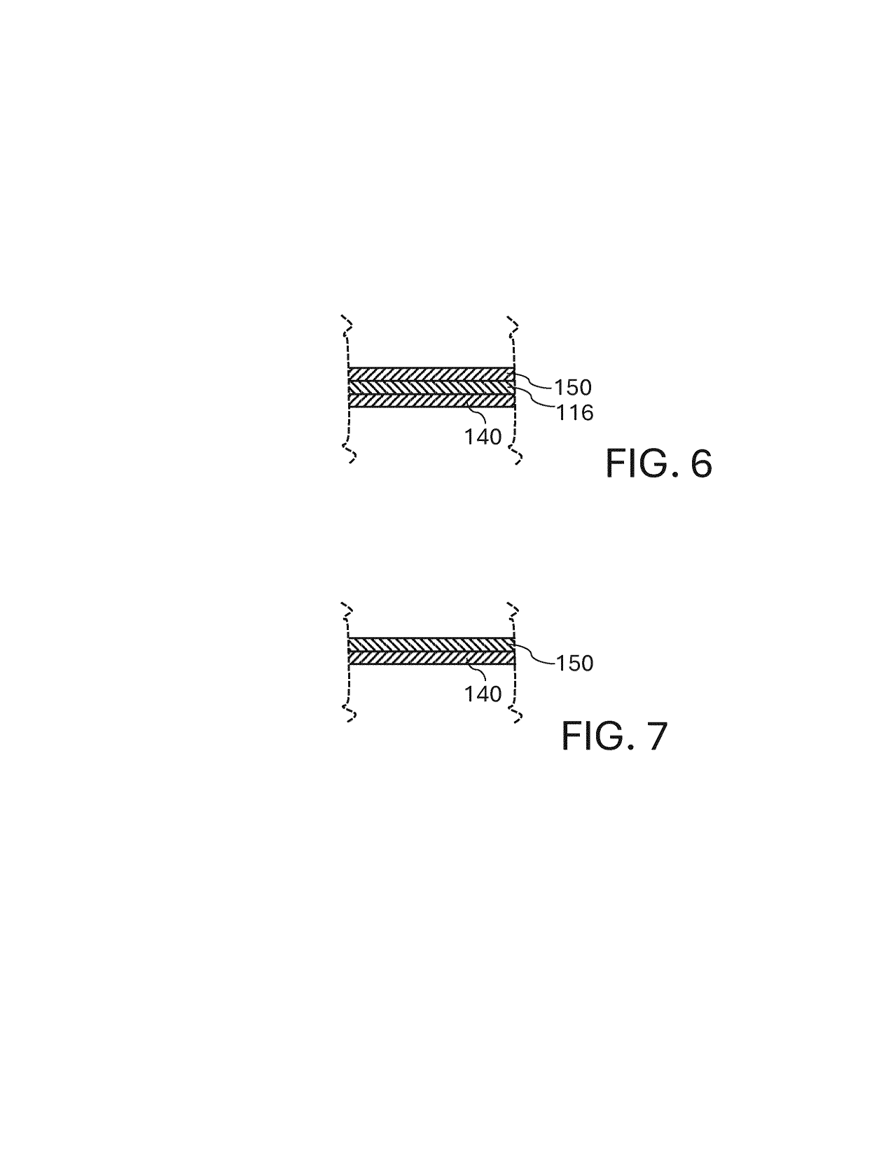

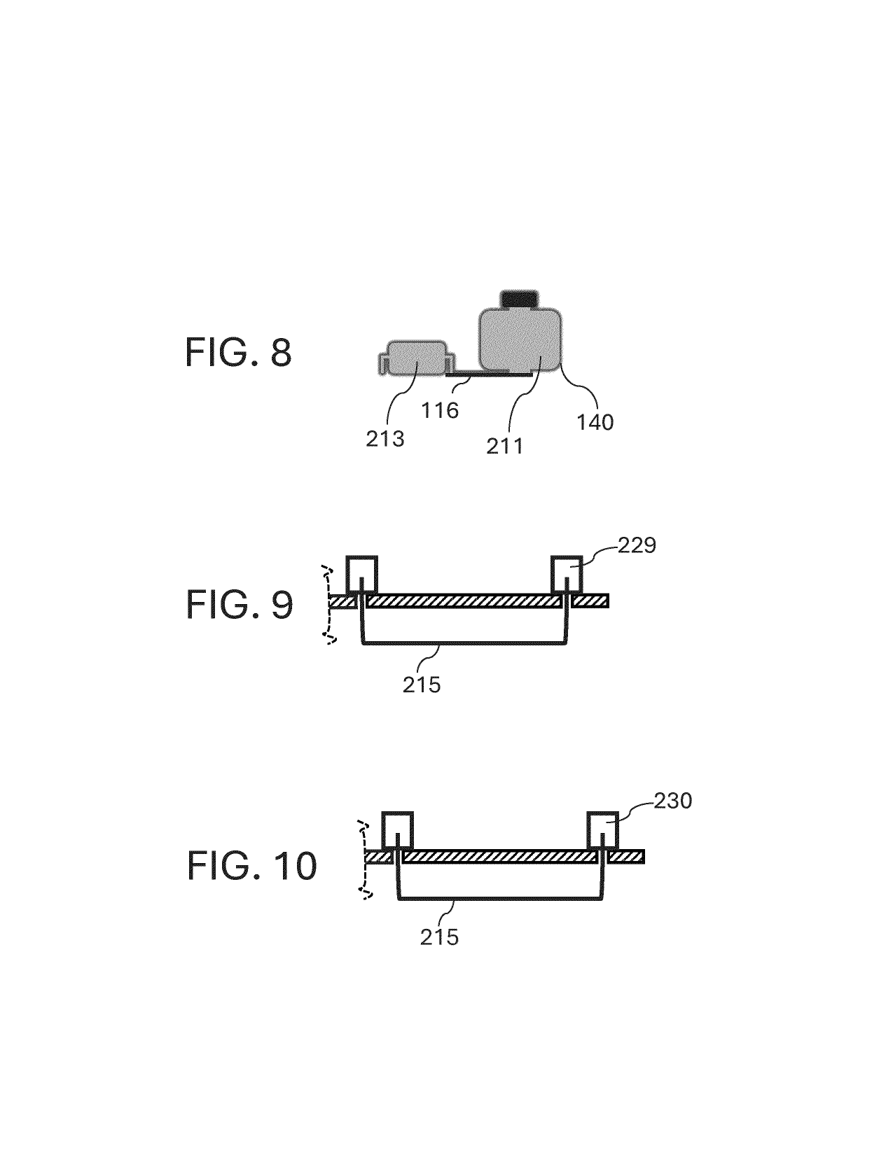

Embodiments of a discharge electrode 215 are made of tungsten, nickel-chromium, stainless steel, or some other electrically conductive and corrosion-resistant material. A simple and effective discharge electrode 215 can be made from 316 stainless steel wire (0.1-2 mm diameter) bent into squared C shapes, as shown in FIG. 3A. The discharge electrodes 215 are spaced by a few cm to ensure optimal plasma coverage over the treated liquid surface 430 but minimize interactions between adjacent discharge electrodes 215. The specific spacing will depend on operating parameters and component properties.

The PCB 115 comprises a plurality of discharge electrodes 215 electrically connected to high voltage traces 116, with supporting electrical circuitry 250 that delivers high-voltage pulses to each discharge electrode 215.

An embodiment of the supporting electrical circuitry 250 can also be called the capacitor-diode power networks. In an embodiment, the supporting electrical circuitry 250 is the capacitors 211, fuses 212, diodes 213, and wires 311 connecting the capacitors. In an embodiment, the supporting electrical circuitry 250 is the capacitors 211, diodes 213, and wires 311 connecting the capacitors. Each discharge electrode 215 has a dedicated capacitor 211 and diode 213. Each capacitor 211 has a capacitor mounting pad 111 for mounting. Each diode 213 has diode mounting pads 113 for mounting. The capacitor 211, capacitor mounting pads 111, diode 213, and diode mounting pads 113 can be protected via a conformal insulating coating 140. Or, the capacitor 211, capacitor mounting pads 111, diode 213, and diode mounting pads 113 can be protected because they can reside within a potting box 119, which is on the non-conductive substrate 150. The potting box 119 can be considered part of the PCB 115. The potting box 119 reduces arcing risk and enhances dielectric strength. The potting box 119 can be filled with a conformable dielectric substance 239. The conformable dielectric substance 239 in the potting box 119 can be dielectric oil like transformer oil 214 or epoxy 240.

High voltage connections are on the top of each capacitor 211. A high voltage connections can also be called capacitor connectors 218.

In embodiments there are capacitor-diode circuits 260.

An embodiment of a capacitor-diode circuit 260 is: a capacitor 211; a fuse 212; a diode 213; and high voltage traces 116 connecting the capacitor 211, fuse 212, and diode 213.

An embodiment of a capacitor-diode circuit 260 is: a capacitor 211; a diode 213; and high voltage trace 116 connecting the capacitor 211 and diode 213.

The capacitor-diode circuits 260 are configured to operate at a pulse repetition frequency between 10 Hz to 10 kHz.

In embodiments, the supporting electrical circuitry 250 includes a combination of capacitors 211 and diodes 213 arranged such that the capacitors 211 may be charged in parallel and discharged independently. This configuration allows each discharge electrode 215 to emit a high-voltage pulse without electrical interaction with neighboring discharge electrodes 215, preserving isolation across the system.

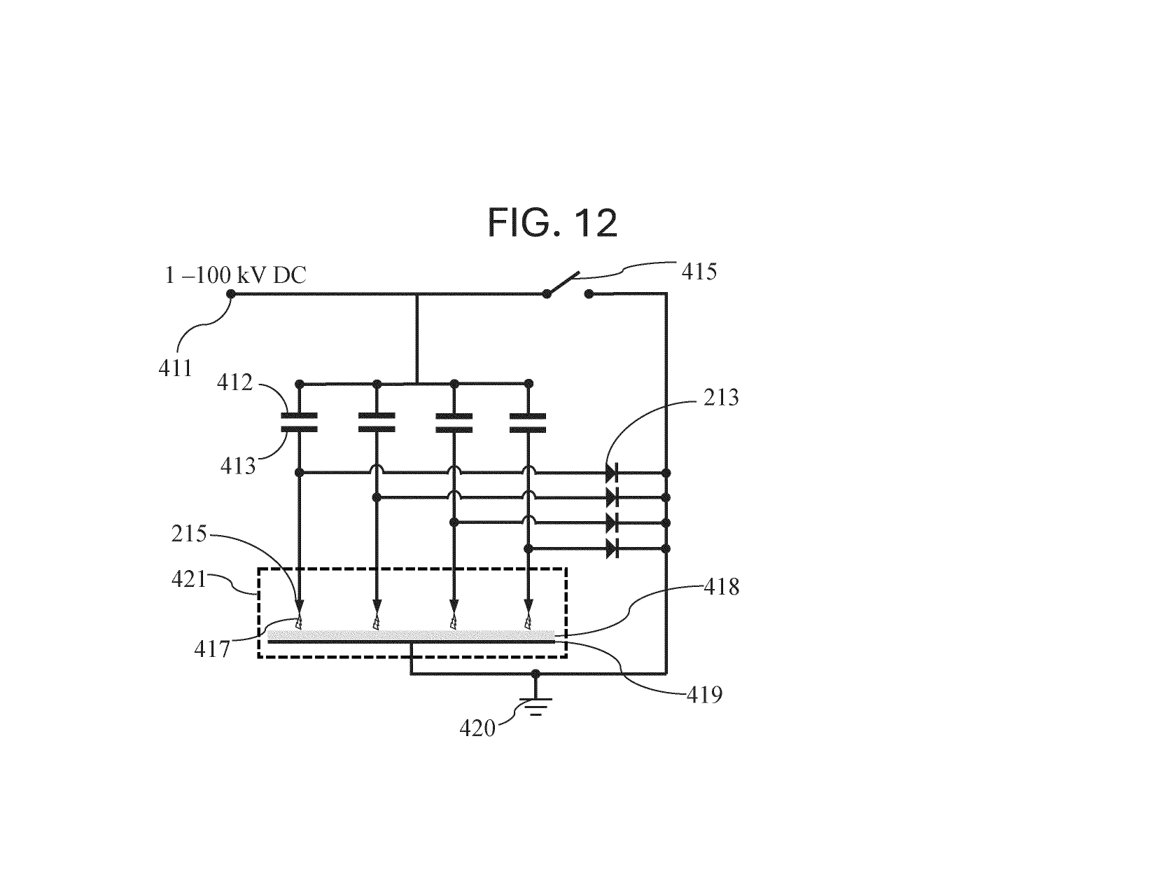

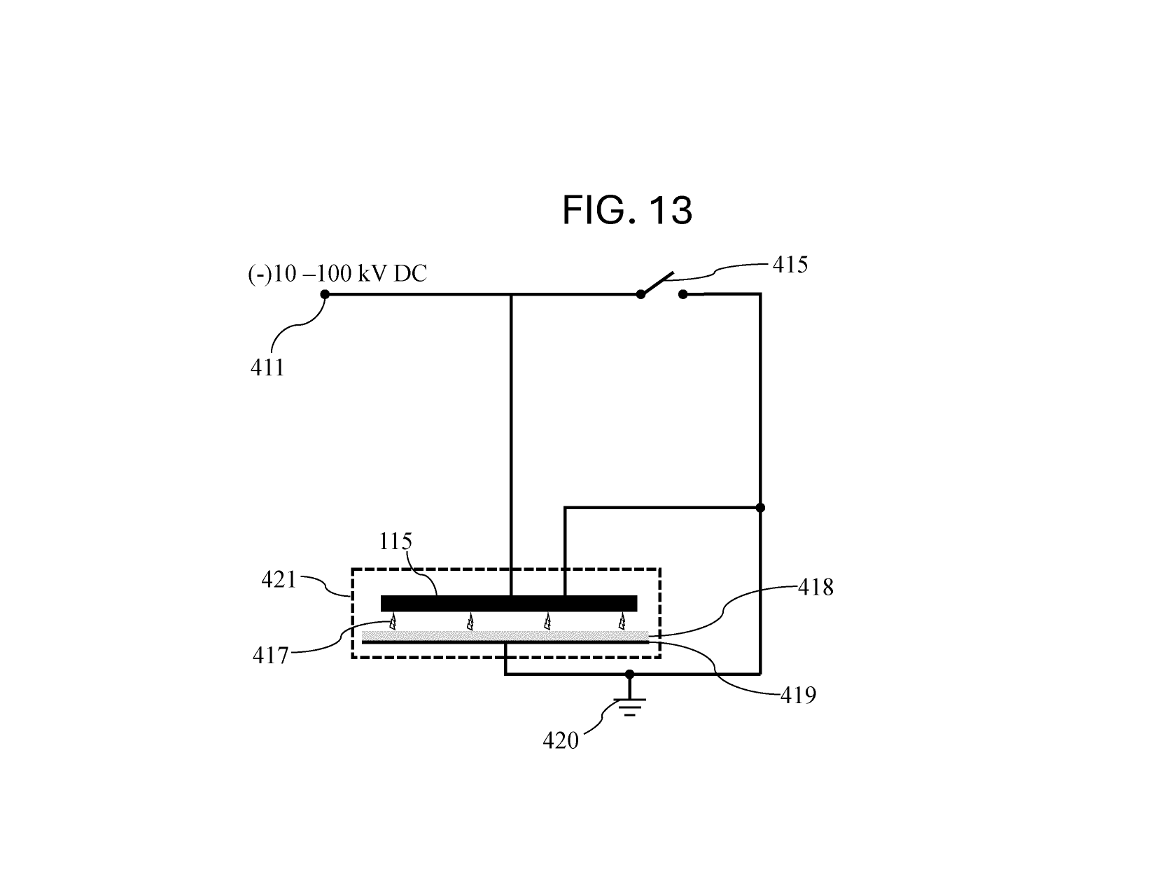

The generalized circuit diagram for the exemplary circuit that is featured on the PCB 115 is shown in FIG. 12, but the elements that comprise these embodiments are compatible with other types of plasma-generating circuits.

Capacitors 211 are rated for 0.1-10 nF and diodes 213 for a reverse voltage that exceeds the specified discharge voltage by at least 20% to account for transient spikes (typically 10-50 kV).

An embodiment of the PCB 115 can include slots 120 in the non-conductive substrate 150. The multiple slots 120 are included for isolation of a discharge electrode 215 and gas flow. The PCB 115 incorporates slots 120 (which are precision cut) between discharge electrode mounting pads 114, which serve two purposes: 1) increase the surface distance between adjacent discharge electrodes 215, reducing the risk of high-voltage arcing; and 2) facilitate gas movement, allowing argon or other process gases to flow freely, enhancing plasma stability.

An embodiment of the failure protection with fuses can be described with the following features. Fuses 212 can be installed in between the capacitor 211 and ground, as shown in FIG. 3A between the capacitor 211 and the diode 213. Due to the high-voltage pulsed nature of the system, these fuses 212 must be carefully rated to withstand transient currents while still breaking under a sustained fault condition. Fuses 212 can be potted inside the same dielectric-filled enclosure, or called the potting box 119, as the capacitor-diode network, ensuring reliable insulation and fault protection.

In embodiments, the conformal coating 140 is applied to the PCB 115 and components, protecting against arc-over and environmental degradation. In certain embodiments, the conformal coating 140 is a urethane or urethane formulation selected for compatibility with the reactive gases and solvents that may be present during fluid treatment processes.

The present embodiments provide a PCB configured to generate multiple plasma discharges across a treated liquid surface 430. The discharge electrodes 215 are positioned above a treatment zone such that a discharge can propagate towards and upon the surface of the liquid to be treated.

Embodiments of the technology include a discharge circuit 280.

An embodiment of a discharge circuit 280 is: a capacitor 211; diode 213; discharge electrode 215; and high voltage traces 116 connecting the capacitor 211, diode 213, and discharge electrode 215.

An embodiment of a discharge circuit 280 is: a capacitor 211; fuse 212; diode 213; discharge electrode 215; and high voltage traces 116 connecting the capacitor 211, fuse 212, diode 213, and discharge electrode 215.

Embodiments of a discharge circuit 280 contain a capacitor-diode circuit 260. Where the capacitor-diode circuit 260 is: a capacitor 211; fuse 212; diode 213; and high voltage traces 116 connecting the capacitor 211, fuse 212, and diode 213. Or the capacitor-diode circuit 260 is: a capacitor 211; diode 213; and high voltage trace 116 connecting the capacitor 211 and diode 213.

Some embodiments integrate the high-voltage power supply directly onto the PCB. Alternatively, external power supplies may be connected through dedicated terminals, as a grounding pad 118 and high voltage power cable 312. In both configurations, the system supports flexible power delivery architectures, including single or multiple supply arrangements.

During development there was experimental observations and qualitative benefits to the described technology. There was reduction in complexity and assembly time. A traditional wired discharge electrode array with 100 electrodes requires 100 separate high-voltage connections, whereas this PCB-based system reduces it to just two (HV & Ground). While assembly time is reduced significantly due to the PCB 115 containing most of the intricate wiring, there’s an even greater benefit pertaining to maintenance requirements. The system down time required to complete maintenance is extremely low, as full PCBs can be quickly removed from the reactor enclosure and replaced with functioning PCBs, enabling maintenance to occur outside of the enclosure. This is not practical when using traditional systems due to the multitude of electrical connections that must be disconnected prior to removal of the electrode array. The embodiments of the PCB 115 enable compact, modular, and scalable treatment of fluids.

The PCB can be mechanically reinforced to withstand vibration, thermal cycling, and handling during maintenance or installation. This reinforcement are mechanical reinforcements structures 220, which are a thickened elements of the non-conductive substrate 150. Alignment features may be included to facilitate drop-in placement into larger rack systems or flow-through modules. These systems can be scaled by arranging multiple PCBs in series or parallel configurations, each operating independently or in coordination.

This architecture supports rapid, high-voltage plasma discharges across the surface of flowing liquids. The layout is optimized to expose a large surface area to plasma contact, making it well-suited for the treatment of brines, wastewater, and other difficult-to-treat fluids. The modularity and manufacturing compatibility of the system allow for cost-effective deployment in both permanent and mobile applications.

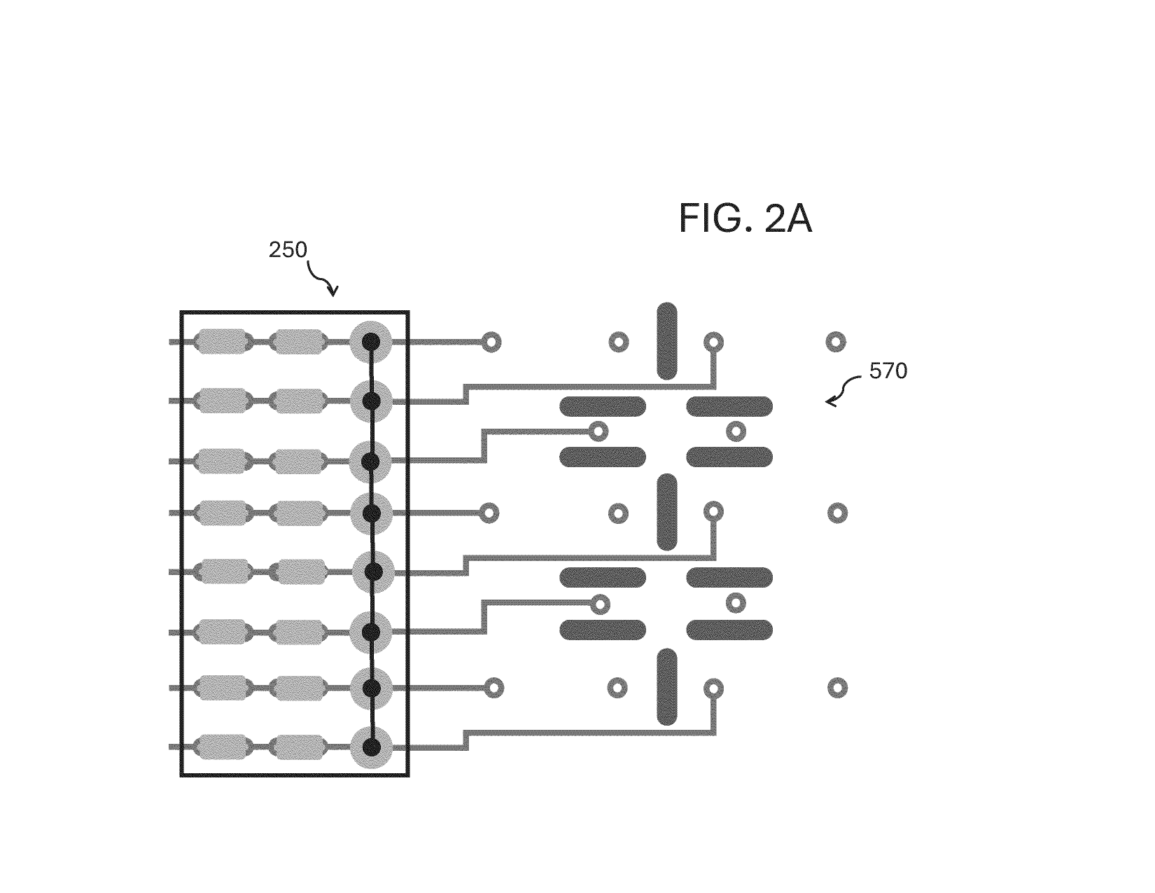

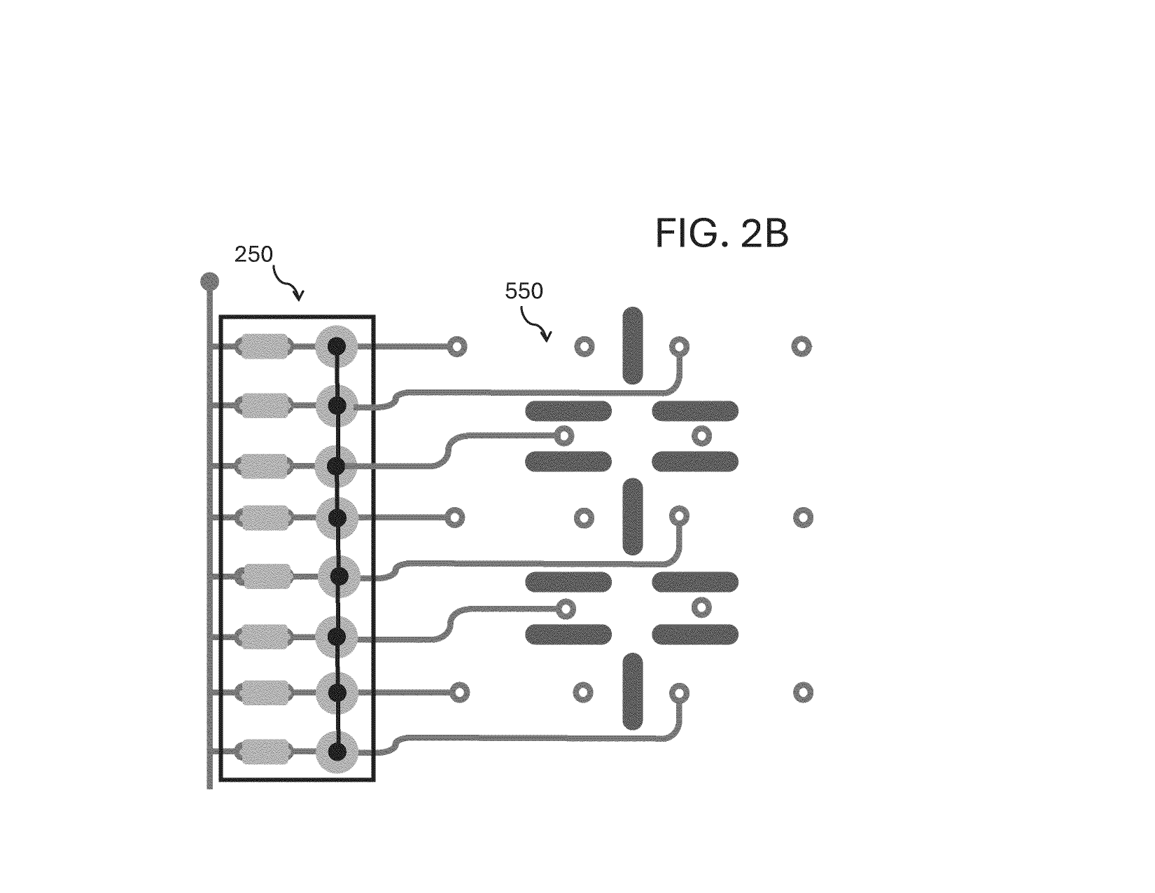

An embodiment can include: each PCB (2.4mm thick FR4 with 2oz copper) is 24x36”; traces are ~1mm thick; each PCB has 48 capacitor-diode-electrode assemblies; operating voltage will be 19-25 kV; discharge frequency will be 50-80 Hz; total power output of each PCB will be 700-800 W; each capacitor is 1nF and rated for 30kV; each diode is rated for 40 kV and 100mA; fuses are not present; 1.25”x3/16” slots will be carved between adjacent electrodes; electrodes are positioned in staggered grid; electrodes are made from 0.8 mm 316 stainless steel wire, and are about 2” long. Discharge electrodes arranged in a staggered pattern 570 is depicted in FIG. 2A.

FIG. 12 shows an embodiment of a generalized circuit diagram for the plasma-generating system shown on the PCB. In this circuit, a bank of four capacitors is charged in parallel by an external power supply 411, which can also be called a high-voltage power source. When triggered, the common sides of the capacitors 412 discharge through a high voltage switch 415, while the isolated sides of capacitors 413 discharge through their respective discharge electrodes 215 to generate plasma 417, which then makes contact with the treated liquid surface 430 of the treated liquid 418. Diodes 213 are used to isolate each capacitor from common ground 420 during discharge, while allowing current to pass during the charge cycle.

The energy flow through the circuit can be described following a general arrangement. In this system, energy flows from a high-voltage power supply into a network of small circuits—each connected to a separate discharge electrode 215 on the printed circuit board (PCB) 115. Every circuit includes two key parts: a capacitor 211 (which stores electrical energy like a battery but with the ability to charge and discharge extremely fast) and a diode 213 (which acts like a one-way check valve, allowing current to flow in only one direction).

The energy flow through the circuit can be described as having a charging phase. The charging phase can be described as follows. The power supply sends high-voltage electricity to all the circuits at once by charging the common/shared sides of the capacitors. During this charging phase, the diodes 213 are open, which allows current to flow from ground to the isolated sides of the capacitors (capacitors must always have a net charge of zero, so if one side is charged to some degree, the other side must be charged to an equal and opposite degree). As a result, every capacitor 211 gets charged such that the voltage increases to the set discharge voltage.

The energy flow through the circuit can be described as having a discharge phase. The discharge phase can be described as follows. When voltage reaches the set discharge voltage, it triggers the spark gap switch, which prompts all of the capacitors 211 to discharge their common sides simultaneously through the spark gap to ground. This effectively causes a reversal in the current on both sides of the capacitors, which causes the diodes to shut, blocking the current from the isolated sides of the capacitors from reaching ground and forcing the isolated sides of the capacitors to instead discharge through the discharge electrodes, which generates plasma across the small gap to the surface of the liquid being treated. The electric current then flows through the liquid (which is conductive) to reach a grounded plate that the liquid is flowing over.

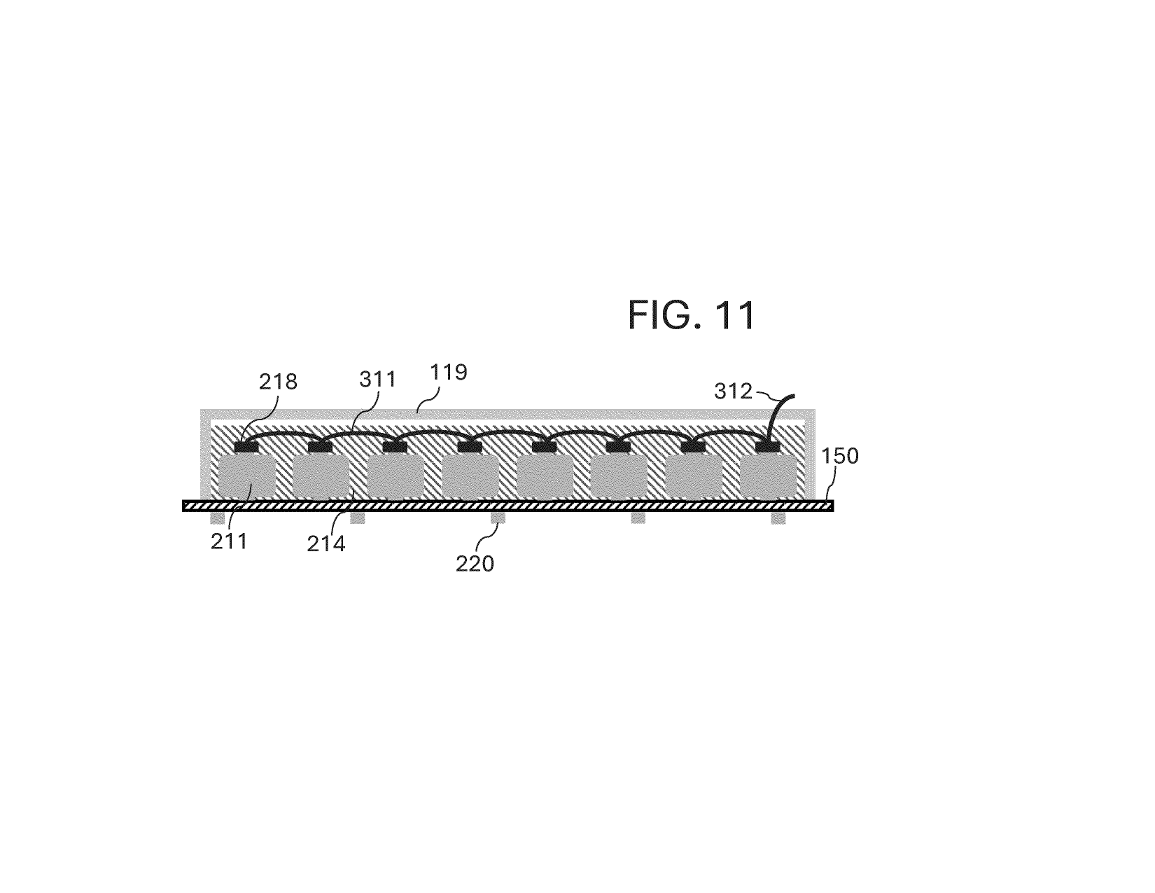

The figures of FIG. 3A-3C and 9-11 depict cross sectional views of the embodiments, where some of the elements have hatching to indicate the view is cross sectional, but other elements do not have hatching for clarity of the elements, where hatching could have been included, such as the capacitor 211, fuse 212, diode 213, electrode connector 217, capacitor connectors 218, mechanical reinforcements structures 220, solderless mechanical connector 229, through-hole spring-clamp connector terminal 230, and the walls of elements.

Components of embodiments of the technology can be described as:

capacitor mounting pads 111

diode mounting pads 112

fuse mounting pads 113

discharge electrode mounting pads 114

printed circuit board (PCB) 115

high voltage trace 116

grounded trace 117

grounding pad 118

potting box 119

slot 120

anterior cut-away line 121

lateral cut-away line 122

conformal insulating coating 140

non-conductive substrate 150

capacitor 211

fuse 212

diode 213

transformer oil 214

discharge electrode 215

electrode through-holes 216

electrode connector 217

capacitor connectors 218

mechanical reinforcements structures 220

solderless mechanical connector 229

through-hole spring-clamp connector terminal 230

conformable dielectric substance 239

epoxy 240

supporting electrical circuitry 250

capacitor-diode circuit 260

discharge circuit 280

wires 311

high voltage power cable 312

external power supply 411

common sides of capacitors 412

isolated sides of capacitors 413

high voltage switch 415

plasma 417

treated liquid 418

grounded electrode 419

common ground 420

reactor enclosure 421

treated liquid surface 430

traces are shaped in the form of curvature, serpentine patterns, or edge chamfering 550

staggered pattern 570

1. An apparatus, comprising:
a printed circuit board (PCB), the PCB comprising:
discharge electrodes; and
traces, each discharge electrode is electrically connected to a trace, the apparatus is configured to provide isolated high-voltage discharges from each of the discharge electrodes.

2. The apparatus of claim 1, comprising:
the PCB can withstand high-voltage of 10 to 50 kV.

3. The apparatus of claim 2, further comprising:
the PCB further comprising:
supporting electrical circuitry comprising:
capacitor-diode circuits, each capacitor-diode circuit comprising:
a capacitor;
a diode; and
a high voltage trace, each capacitor-diode circuit is electrically connected to a discharge electrode.

4. The apparatus of claim 3, comprising:
the capacitor-diode circuits are configured to operate at a pulse repetition frequency between 10 Hz to 10 kHz.

5. The apparatus of claim 3, further comprising:
the PCB further comprising:
a potting box, the potting box houses at least a portion of the supporting electrical circuitry, the potting box is filled with a conformable dielectric substance.

6. The apparatus of claim 5, comprising:
the potting box is configured to be refillable with the conformable dielectric substance allowing for maintenance or reconfiguration of the supporting electrical circuitry.

7. The apparatus of claim 2, further comprising:
the PCB further comprising:
a non-conductive substrate; and
solderless mechanical connectors, the discharge electrodes are removably connected to the non-conductive substrate with the solderless mechanical connectors.

8. The apparatus of claim 7, comprising:
the solderless mechanical connectors are through-hole spring-clamp connector terminals.

9. The apparatus of claim 2, further comprising:
the PCB further comprising:
a non-conductive substrate; and
slots, the slots are in the non-conductive substrate.

10. The apparatus of claim 7, further comprising:
the PCB further comprising:
slots, the slots are in the non-conductive substrate, the slots are configured where at least one slot is in between at least one solderless mechanical connector of adjacent discharge electrodes.

11. The apparatus of claim 2, further comprising:
the PCB further comprising:
a conformal insulating coating, the conformal insulating coating covers at least the traces.

12. The apparatus of claim 3, further comprising:
the PCB further comprising:
discharge circuits, each discharge circuit comprising:
a capacitor-diode circuit;
a high voltage trace; and
a discharge electrode; and
the supporting electrical circuitry further comprising:
each capacitor-diode circuit further comprising:
a fuse, the fuses are configured to isolate individual discharge circuits in the event of a fault.

13. The apparatus of claim 3, comprising:
the supporting electrical circuitry is configured where each discharge electrode is electrically isolated from all the other discharge electrodes during operation of the apparatus.

14. The apparatus of claim 3, further comprising:
the PCB further comprising:
discharge circuits, each discharge circuit comprising:
a capacitor-diode circuit;
a high voltage trace; and
a discharge electrode, the supporting electrical circuitry is configured where all the discharge circuits charge in parallel and discharge independently through the discharge electrode of each discharge circuit.

15. The apparatus of claim 2, further comprising:
a treated liquid; and
a surface of the treated liquid, the discharge electrodes are configured where the discharge electrodes are positioned to emit plasma toward the surface of the treated liquid.

16. The apparatus of claim 2, further comprising:
an external power supply; and
the PCB further comprising:
one or more terminals, the one or more terminals are configured to receive high-voltage power and ground from the external power supply.

17. The apparatus of claim 2, further comprising:
a treated liquid; and
a surface of the treated liquid, the discharge electrodes are configured in a staggered pattern to provide uniform plasma distribution to the surface of the treated liquid.

18. The apparatus of claim 2, comprising:
the traces are shaped in the form of curvature, serpentine patterns, or edge chamfering to reduce electric field concentration and arcing risk.

19. The apparatus of claim 2, further comprising:
the PCB further comprising:
a non-conductive substrate; and
mechanical reinforcements structures, the mechanical reinforcements structures form portions of the non-conductive substrate, the mechanical reinforcements structures are configured to prevent warping of the non-conductive substrate under thermal or vibrational load during operation of the apparatus.

20. The apparatus of claim 2, comprising:
the discharge electrodes are configured to be interchangeable with discharge electrodes of differing shape, material, or length.
